(19) United States
(12) Patent Application Publication
(10) Pub. No.: US 2020/0260534 A1
(43) Pub. Date: Aug. 13, 2020

(54) HEATING MODULE AND SEMICONDUCTOR FABRICATING SYSTEM INCLUDING THE SAME

(71) Applicant: SAMSUNG ELECTRONICS CO., LTD., Suwon-si (KR)

(72) Inventors: YOUNGHO HWANG, Hwaseong-si (KR); Chulmin Cho, Seoul (KR); Seok Heo, Hwaseong-si (KR)

(21) Appl. No.: 16/656,054

(22) Filed: Oct. 17, 2019

(30) Foreign Application Priority Data
Feb. 11, 2019 (KR) 10-2019-0015455

(51) Int. Cl. H05B 6/06; H01L 21/67; H05B 1/02; H05B 6/44; H05B 6/04

(52) U.S. Cl. CPC H05B 6/06; H01L 21/67248; H05B 1/0233; H05B 6/44; H05B 6/04; H05B 1/0202

(57) ABSTRACT

A heating module including: a plate including heating regions; heater coils disposed in the heating regions; a power source supplying an electric power to the heater coils; a switching circuit connected to the heater coils and the power source to control the electric power; temperature sensors disposed in the heating regions to sense temperatures of the heating regions; current sensors connected to the switching circuit and the heater coils to sense currents supplied to the heater coils; and a heating controller connected to the temperature sensors and the current sensors to measure temperatures of the heating regions. The heating controller is configured to detect the currents supplied to the heater coils and provides a maximum power to the heater coils regardless of a resistance difference of the heater coils, when a measured temperature is less than a predetermined temperature.

### CROSS-REFERENCE TO RELATED APPLICATION

This U.S. non-provisional patent application claims priority under 35 U.S.C. § 119 to Korean Patent Application No. 10-2019-0015455, filed on Feb. 11, 2019, in the Korean Intellectual Property Office, the disclosure of which is incorporated by reference herein in its entirety.

### TECHNICAL FIELD

The present inventive concept relates to a system of fabricating a semiconductor device, and more particularly, to a heating module, which is used to heat a substrate, and a semiconductor fabricating system including the same.

### DISCUSSION OF THE RELATED ART

Generally, a semiconductor device is fabricated through a plurality of unit processes. The unit processes include a thin film deposition process, a photolithography process, an etching process, and a cleaning process. For example, the photolithography process is a process to form a photoresist pattern on a substrate. For example, the photolithography process may include steps of coating, baking, exposing, and developing a photoresist layer disposed on the substrate. In the baking step, a heating module is used to heat the substrate and consequently to cure the photoresist layer.

### SUMMARY

According to an exemplary embodiment of the present inventive concept, a heating module including: a plate including a plurality of heating regions; a plurality of heater coils disposed in the plurality of heating regions; a power source supplying an electric power to the plurality of heater coils; a switching circuit connected to the plurality of heater coils and the power source to control the electric power; temperature sensors disposed in the plurality of heating regions to sense temperatures of the plurality of heating regions; current sensors connected to the switching circuit and the plurality of heater coils to sense currents supplied to the plurality of heater coils; and a heating controller connected to the temperature sensors and the current sensors to measure temperatures of the heating regions, wherein the heating controller is configured to detect the currents supplied to the plurality of heater coils and provides a maximum power to the heater coils regardless of a resistance difference of the plurality of heater coils, when a measured temperature is less than a predetermined temperature.

According to an exemplary embodiment of the present inventive concept, a heating module including: a plate including first and second heating regions; first and second heater coils disposed in the first and second heating regions, respectively; a power source supplying an electric power to the first and second heater coils; first and second switches connected to the power source and the first and second heater coils, respectively, to control the electric power; current sensors connected to the first and second switches and the first and second heater coils, wherein the current sensors are configured to sense currents provided to the first and second heater coils; and a heating controller configured to detect currents provided to the first and second heater coils by using sensing signals received from the current sensors, wherein the heating controller provides a first maximum power to the first heater coil with a same value regardless of a resistance difference between the first and second heater coils, and wherein the heating controller provides a second maximum power to the second heater coil with a same value as the first maximum power regardless of a resistance difference between the first and second heater coils.

According to an exemplary embodiment of the present inventive concept, a system of fabricating a semiconductor device including: a spin coater coating a photoresist layer on a substrate; and a baking device including a heating module configured to heat the substrate and to cure the photoresist layer. The heating module includes: a plate including first and second heating regions; first and second heater coils disposed in the first and second heating regions, respectively; a power source supplying an electric power to the first and second heater coils; first and second switches connected to the power source and the first and second heater coils, respectively, to control the electric power; current sensors connected to the first and second switches and the first and second heater coils and are configured to sense currents provided to the first and second heater coils; and a heating controller configured to detect current provided to the first and second heater coils by using sensing signals received from the current sensors, wherein the heating controller provides a first maximum power to the first heater coil with a same value regardless of a resistance difference between the first and second heater coils, and wherein the heating controller provides a second maximum power to the second heater coil with a same value as the first maximum power regardless of a resistance difference between the first and second heater coils.

### BRIEF DESCRIPTION OF THE DRAWINGS

The above and other features of the present inventive concept will become more apparent by describing in detail exemplary embodiments thereof, with reference to the accompanying drawings, in which:

FIG. 1 is a plan view illustrating a system of fabricating a semiconductor device, according to an exemplary embodiment of the present inventive concept;

FIG. 2 is an exploded perspective view illustrating a baking device of FIG. 1 according to an exemplary embodiment of the present inventive concept;

FIG. 3 is a diagram illustrating a heating module of FIG. 2 according to an exemplary embodiment of the present inventive concept;

FIG. 4 is a plan view of a plate of FIG. 3 according to an exemplary embodiment of the present inventive concept;

FIG. 5 is a diagram illustrating a heating controller of FIG. 3 according to an exemplary embodiment of the present inventive concept;

FIG. 6 is a graph illustrating a first constant voltage power of a center heater coil and a second constant voltage power of a middle heater coil, which are controlled by a conventional temperature control unit;

FIG. 7 is a graph illustrating a first temperature of a center heater coil and a second temperature of a middle heater coil, which are heated by first and second constant voltage powers of FIG. 6;

FIG. 8 is a graph illustrating a first reference resistance and a second reference resistance of a center heater coil and a middle heater coil of FIG. 3 according to an exemplary embodiment of the present inventive concept;

FIG. 9 is a graph illustrating a first power of a center heater coil and a second power of a middle heater coil;

FIG. 10 is a graph illustrating a third temperature of a center region and a fourth temperature of a middle region;

FIG. 11 is a diagram illustrating a heating module of FIG. 2 according to an exemplary embodiment of the present inventive concept;

FIG. 12 is a diagram illustrating a heating module of FIG. 2 according to an exemplary embodiment of the present inventive concept;

FIG. 13 is a flow chart illustrating a method of fabricating a semiconductor device, according to an exemplary embodiment of the present inventive concept; and

FIG. 14 is a flow chart illustrating a step of heating a substrate of FIG. 1 according to an exemplary embodiment of the present inventive concept.

### DETAILED DESCRIPTION OF THE EMBODIMENTS

Exemplary embodiments of the present inventive concept will now be described in more detail with reference to the accompanying drawings, in which exemplary embodiments of the present inventive concept are shown.

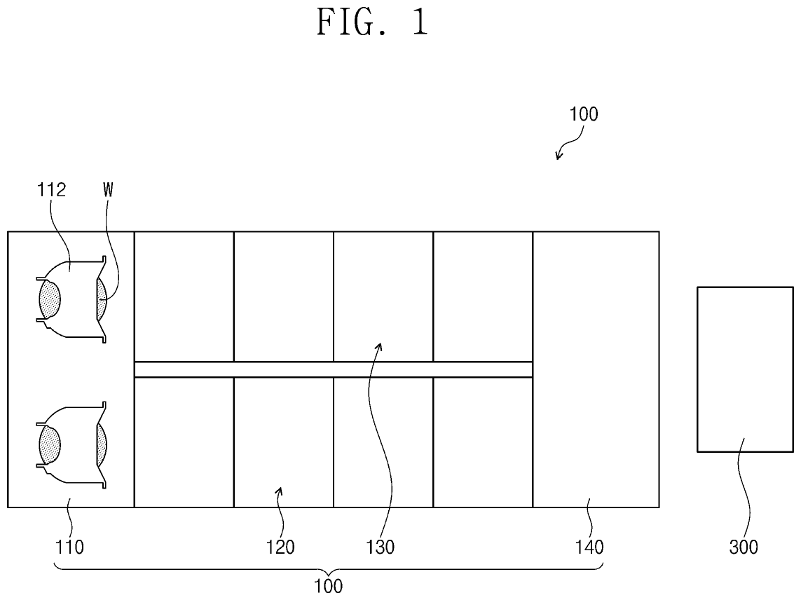

FIG. 1 illustrates a system 100 of fabricating a semiconductor device, according to an exemplary embodiment of the present inventive concept.

Referring to FIG. 1, the fabrication system 100 may be a spinner system. As an example, the fabrication system 100 may include an index device 110, a spin coater 120, a baking device 130, and a developing device 140. The index device 110 may provide a substrate W, which is contained in a carrier 112, to the spin coater 120. The spin coater 120 may be configured to perform a coating process of forming a photoresist layer on the substrate W. The baking device 130 may be configured to heat the substrate W and consequently to cure the photoresist layer formed on the substrate W. For example, an exposure device 300 may be provided near the developing device 140. The exposure device 300 may be configured to irradiate a portion of the photoresist layer on the substrate W with light. The developing device 140 may be configured to develop the irradiated photoresist layer to form a photoresist pattern on the substrate W. For example, the photoresist pattern may be formed in a photolithography process and an etching process performed by the developing device 140. The substrate W may be reloaded in the carrier 112. In an exemplary embodiment of the present inventive concept, the fabrication system 100 may be a thin film deposition system or an etching system, but the present inventive concept is not limited to thereto.

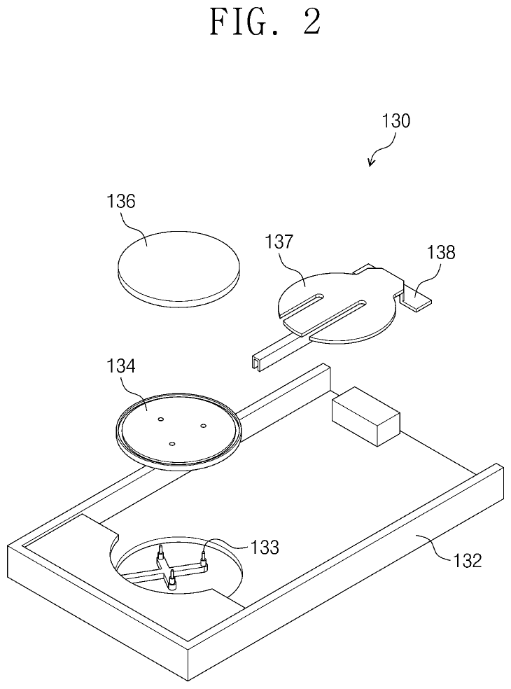

FIG. 2 illustrates the baking device 130 of FIG. 1 according to an exemplary embodiment of the present inventive concept.

Referring to FIG. 2, the baking device 130 may include a base module 132, a heating module 134, a chamber module 136, and a transfer module 138. The base module 132 may be provided below the heating module 134 and the chamber module 136. The base module 132 may include a lift pin assembly 133. The lift pin assembly 133 may be used to change a vertical position of the substrate W, while the substrate W is located on the heating module 134. For example, the lift pin assembly 133 may lift up the substrate W. The heating module 134 may be used to heat the substrate W. The chamber module 136 may be provided on the heating module 134. For example, the chamber module 136 may cover the substrate W. When the chamber module 136 is disposed on the heating module 134 to cover the substrate W, the heating module 134 may heat the substrate W to cure the photoresist layer. If the chamber module 136 is moved to open the heating module 134, the transfer module 138 may load or unload the substrate W on or from the lift pin assembly 133. For example, the transfer module 138 may provide the substrate W to the plate 150 when the chamber module 136 opens the heating module 134. The transfer module 138 may include a blade 137 for loading or supporting the substrate W.

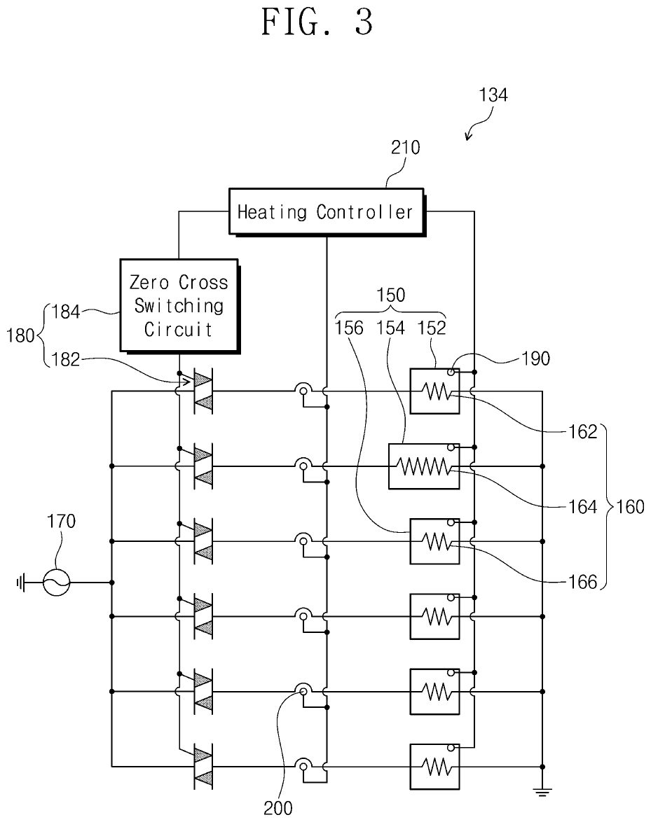

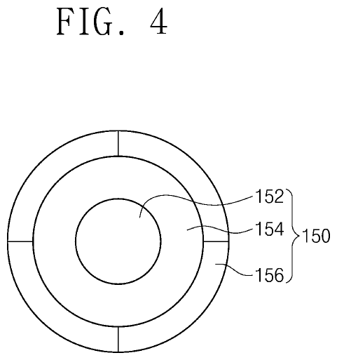

FIG. 3 illustrates the heating module 134 of FIG. 2 according to an exemplary embodiment of the present inventive concept. FIG. 4 is a plan view of a plate 150 of FIG. 3 according to an exemplary embodiment of the present inventive concept.

Referring to FIG. 3, the heating module 134 may include a plate 150, a plurality of heater coils 160, a power source 170, a switching unit 180, a plurality of temperature sensors 190, a plurality of current sensors 200, and a heating controller 210.

Referring to FIGS. 3 and 4, the plate 150 may have a circular shape, when viewed in a plan view. However, the present inventive concept is not limited thereto, and the plate 150 may have, for example, a polygonal shape. The plate 150 may include a plurality of heating regions. For example, the plate 150 may have six heating regions. As an example, the plate 150 may include a center region 152, a middle region 154, and a plurality of edge regions 156. The center region 152 may be enclosed and surrounded by the middle region 154 and the edge regions 156. For example, the center region 152 may be shaped like a circular disc. The middle region 154 may be disposed between the center region 152 and the edge regions 156. For example, the middle region 154 may have a ring shape or a circular shape including an opening. The edge regions 156 may be disposed outside the middle region 154. Each of the edge regions 156 may have an are shape. As an example, an area of the middle region 154 may be larger than an area of the center region 152 and may be larger than an area of each of the edge regions 156. For example, the area of the middle region 154 may be about 5% larger than the area of the center region 152. For example, the radius of the middle region 154 may be larger than that of the center region 152. In an exemplary embodiment of the present inventive concept, the area of the middle region 154 may be substantially equal to the area of the center region 152 and may be substantially equal to the area of each of the edge regions 156.

Referring to FIG. 3, the heater coils 160 may be disposed in the center region 152, the middle region 154, and the edge regions 156 of the plate 150. As an example, the heater coils 160 may include a center heater coil 162, a middle heater coil 164, and a plurality of edge heater coils 166. The center heater coil 162 may be disposed in the center region 152. The middle heater coil 164 may be disposed in the middle region 154. The edge heater coils 166 may be disposed in the edge regions 156, respectively. The center heater coil 162, the middle heater coil 164, and the edge heater coils 166 may have resistances different from each other. As an example, the resistances of the center heater coil 162, the middle heater coil 164, and the edge heater coils 166 may have a difference or deviation of about ±5% from each other. For example, the resistance of each of the edge heater coils 166 may be equal to the resistance of the center heater coil 162. For example, the resistance of the middle heater coil 164 may be higher than the resistances of the center heater coil 162 and the edge heater coils 166. For example, the resistance of the middle heater coil 164 may be about 5% higher than the resistances of the center heater coil 162 and/or the edge heater coils 166. In an exemplary embodiment of the present inventive concept, the resistance of the middle heater coil 164 may be equal to the resistances of the center heater coil 162 and the edge heater coils 166.

The power source 170 may be connected to one terminal that is connected to each of the heater coils 160. The other terminals of the heater coils 160 may be grounded. The power source 170 may supply an electric power to the center heater coil 162, the middle heater coil 164 and the edge heater coils 166. For example, the power source 170 may supply an AC power to the heater coils 160.

The switching unit 180 may be provided between and connected to the power source 170 and the heater coils 160. The switching unit (e.g. a circuit) 180 may be configured to perform a switching operation of selectively supplying the electric power to the heater coils 160. As an example, the switching unit 180 may include a plurality of switching devices (e.g. a circuit) 182 and a zero cross switching circuit 184. The switching devices 182 may be provided between and connected to the power source 170 and the heater coils 160. The switching devices 182 may be configured to selectively supply the electric power to the heater coils 160. For example, each of the switching devices 182 may include a triode alternating current switch (TRIAC). The zero cross switching circuit 184 may be provided between and connected to the switching devices 182 and the heating controller 210. The zero cross switching circuit 184 may control a switching time point of the switching devices 182 to prevent the switching devices 182 from being damaged by sparks or electrical discharges. Whenever the phase of the electric power becomes 0, the zero cross switching circuit 184 may turn the switching devices 182 on or off, based on a control signal transmitted from the current control unit 216.

The temperature sensors 190 may be disposed near the heater coils 160, respectively, in the plate 150. The temperature sensors 190 may be connected to the heating controller 210. The temperature sensors 190 may sense temperatures of the heater coils 160. For example, each of the temperature sensors 190 may include a thermocouple.

The current sensors 200 may be provided between the switching devices 182 and the heater coils 160. The current sensors 200 may be connected to the heating controller 210. The current sensors 200 may sense a current to be supplied to the heater coils 160. For example, each of the current sensor 200 may include a current prober (I-prober).

The heating controller 210 may be connected to the switching unit 180, the temperature sensors 190, and the current sensors 200. The heating controller 210 may control the switching unit 180 to adjust the electric power supplied to the heater coils 160. The heater coils 160 may heat the plate 150 using the electric power to generate heat. The heating controller 210 may measure temperatures of the plate 150 and the heater coils 160 using sensing signals received from the temperature sensors 190. The heating controller 210 may control the electric power, based on the temperature of the heater coils 160. Resistance values of each of the heater coils 160 according to generated temperatures may be stored in advance in the heating controller 210. The heating controller 210 may detect currents, using the sensing signal of the current sensors 200. The heating controller 210 may control the electric power, based on the detected currents and the stored resistance information of the heater coils 160. If the substrate W is placed on the plate 150, the plate 150 may be temporarily cooled down. In such a case, the heating controller 210 may supply the same power (P=I²R) to the center heater coil 162, the middle heater coil 164, and the edge heater coils 166 to reheat the plate 150 to a reference temperature. If the plate 150 is heated to a predetermined temperature, the heating controller 210 may control the electric power to be supplied to the center heater coil 162, the middle heater coil 164, and the edge heater coils 166, based on the detected currents.

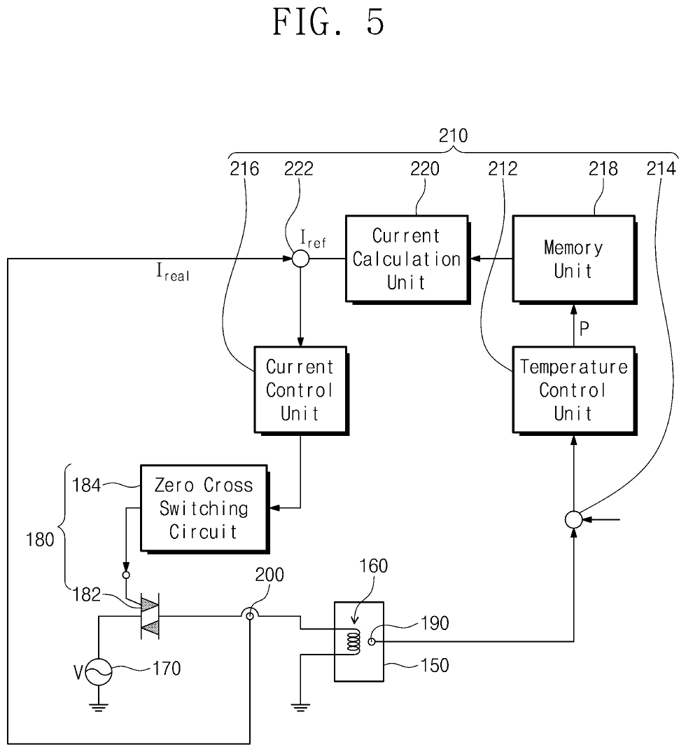

FIG. 5 illustrates the heating controller 210 of FIG. 3 according to an exemplary embodiment of the present inventive concept.

Referring to FIG. 5, the heating controller 210 may include a temperature control unit 212, a temperature instructor 214, a current control unit 216, a memory unit 218, a current calculation unit 220, and a comparison unit 222.

The temperature control unit 212 may be connected to the temperature sensor 190. The temperature control unit 212 may control the temperature of the heater coils 160, based on the reference temperature. For example, the reference temperature may be about 130° C.

The temperature instructor 214 may be provided between and connected to the temperature sensor 190 and the temperature control unit 212. The temperature instructor 214 may compare the measured temperature of the temperature sensor 190 with the reference temperature. For example, the temperature instructor 214 may be a circuit and/or processor that compares the measured temperature with the reference temperature. The temperature control unit 212 may provide results, which are obtained by comparing the measured temperature with the reference temperature, to the current control unit 216, the memory unit 218, the current calculation unit 220, and the comparison unit 222, and these results may be used to adjust the electric power to be supplied to the heater coils 160, based on the current and the resistance.

By contrast, a conventional temperature control unit may heat the heat coil 160 by using a constant voltage (P=V²/R, V is constant) without controlling the current sent through the heat coil 160.

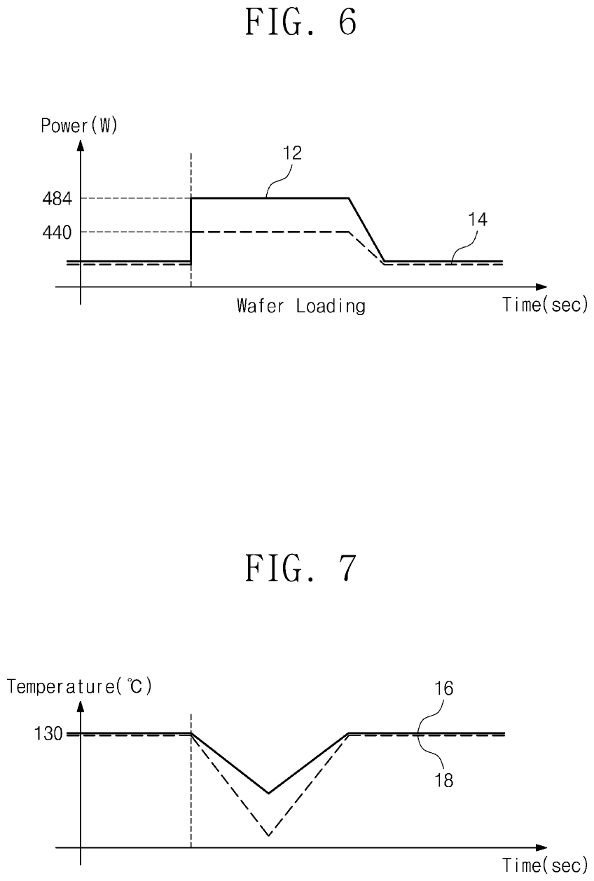

FIG. 6 illustrates a first constant voltage power 12 of the center heater coil 162 and a second constant voltage power 14 of the middle heater coil 164 and which are controlled by a conventional temperature control unit.

Referring to FIG. 6, the first constant voltage power 12 of the center heater coil 162 and the second constant voltage power 14 of the middle heater coil 164 were different from each other. When the plate 150 was cooled down, the first constant voltage power 12 and the second constant voltage power 14 were supplied at the max value. As an example, the largest value of the first constant voltage power 12 was greater than the largest value of the second constant voltage power 14. For example, the largest value of the first constant voltage power 12 may be about 484 W, and the largest value of the second constant voltage power 14 may be about 440 W.

FIG. 7 illustrates a first temperature 16 of the center heater coil 162 and a second temperature 18 of the middle heater coil 164, which are heated by the first and second constant voltage powers 12 and 14 of FIG. 6.

Referring to FIG. 7, the first temperature 16 of the center heater coil 162 and the second temperature 18 of the middle heater coil 164 were temporarily different from each other. For example, the first temperature 16 was temporarily higher than the second temperature 18. For example, the substrate W was temporarily heated in a non-uniform manner. Thus, a control method performed by the conventional temperature control unit using the first and second constant voltage powers 12 and 14 may reduce the heating uniformity of the substrate W and consequently increase a failure rate in a process of curing the photoresist layer.

Referring back to FIG. 5, the current control unit 216 may be provided between and connected to the current sensor 200 and the switching unit 180. The current control unit 216 may determine currents supplied to the heater coils 160 from the current sensing signals of the current sensors 200. The current control unit 216 may control the switching operations of the switching devices 182, based on the currents and/or resistances of the heater coils 160.

The current control unit 216 may calculate the resistance of each of the heater coils 160, based on the currents of the heater coils 160, and may adjust the electric power. The current control unit 216 may store the calculated values of the resistance and the electric power in the memory unit 218. The resistance (e.g., R=P/I²) of each of the heater coils 160 may vary depending on temperature of the heater coils 160.

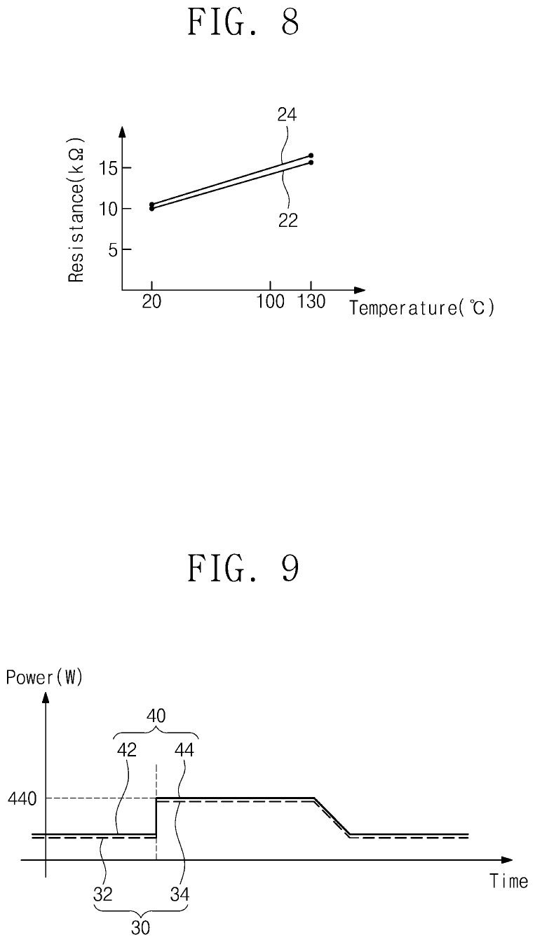

FIG. 8 illustrates a first reference resistance 22 of the center heater coil 162 and a second reference resistance 24 of the middle heater coil 164 of FIG. 3 according to an exemplary embodiment of the present inventive concept.

Referring to FIG. 8, the first reference resistance 22 of the center heater coil 162 and the second reference resistance 24 of the middle heater coil 164 may increase in proportion to temperature. For example, the first reference resistance 22 may be about 10 KΩ at a room temperature (e.g., 20° C.) and about 15KΩ at about 130° C. The second reference resistance 24 may have a higher resistance than that of the first reference resistance 22 at each temperature. For example, the second reference resistance 24 may be about 10.5 KΩ at the room temperature and about 15.65 KΩ at about 130° C.

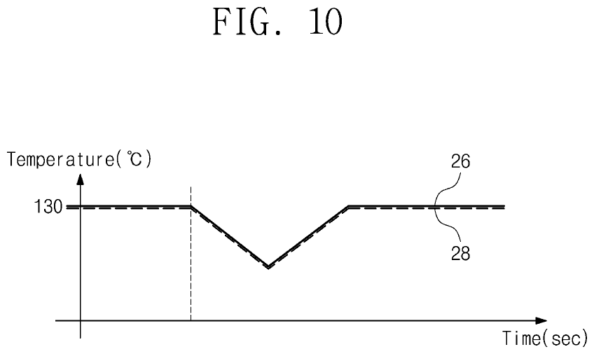

FIG. 9 illustrates a first power 30 of the center heater coil 162 and a second power 40 of the middle heater coil 164. FIG. 10 illustrates a third temperature 26 of the center region 152 of the plate 150 and a fourth temperature 28 of the middle region 154 of the plate 150.

Referring to FIGS. 9 and 10, the current control unit 216 may control the first power 30 of the center heater coil 162 and the second power 40 of the middle heater coil 164 as the same value such that the third temperature 26 of the center region 152 becomes the same as the fourth temperature 28 of the middle region 154.

Referring to FIG. 9, the first power 30 of the center heater coil 162 may be equal to the second power 40 of the middle heater coil 164.

As an example, the first power 30 may include a first normal power 32 and a first maximum power 34. The first maximum power 34 may be greater than the first normal power 32. For example, the first maximum power 34 may be about 440 W.

As an example, the second power 40 may include a second normal power 42 and a second maximum power 44. The second normal power 42 may be similar or equal to the first normal power 32. In an exemplary embodiment of the present inventive concept, the second maximum power 44 may be greater than the second normal power 42. As an example, the second maximum power 44 may be equal to the first maximum power 34, regardless of whether there is a difference between the first reference resistance 22 and the second reference resistance 24. For example, the current control unit 216 may be configured to allow the first maximum power 34 to have the same power as the second maximum power 44, regardless of whether there is a difference between the first reference resistance 22 and the second reference resistance 24.

Referring to FIG. 10, the third temperature 26 of the center heater coil 162 may coincide with the fourth temperature 28 of the middle heater coil 164. The center heater coil 162 and the middle heater coil 164 may be heated such that there is no difference in temperature therebetween. Accordingly, the heating temperature uniformity of the plate 150 may be increased. Thus, it may be possible to prevent a failure from occurring in a process of curing the photoresist layer.

Referring back to FIG. 5, the memory unit 218 may be provided between and connected to the temperature control unit 212 and the current control unit 216. The memory unit 218 may be configured to store information on the first reference resistance 22, the second reference resistance 24, the first normal power 32, the first maximum power 34, the second normal power 42, and the second maximum power 44.

The current calculation unit 220 may be provided between and connected to the memory unit 218 and the current control unit 216. The current calculation unit 220 may calculate a first reference current I_{ref} or a second reference current, based on the temperature of the heater coil 160, the first reference resistance 22, the second reference resistance 24, the first normal power 32, the first maximum power 34, the second normal power 42 and the second maximum power 44. The first reference current I_{ref} may be provided to the center heater coil 162 or each of the edge heater coils 166, and the second reference current may be provided to the middle heater coil 164.

The comparison unit 222 may be provided between and connected to the current control unit 216 and the current sensor 200. If a first measurement current Iᵣₑₐₗ is obtained by the current control unit 216, the comparison unit 222 may compare the first reference current I_{ref} with the first measurement current Iᵣₑₐₗ. The first measurement current Iᵣₑₐₗ transmitted to the center heater coil 162 may be measured by the current sensor 200. For example, the current sensor 200 may be between the power source 170 and the center heater coil 162. The current control unit 216 may set the first measurement current Iᵣₑₐₗ to have the same value as the first reference current I_{ref} and may provide the first normal power 32 and the first maximum power 34 to the center heater coil 162. The comparison unit 222 may compare the second reference current with a second measurement current. The second measurement current transmitted to the middle heater coil 164 may be measured by the current sensor 200. For example, the current sensor 200 may be between the power source 170 and the middle heater coil 164. The current control unit 216 may set the second measurement current to have the same value as the second reference current and may provide the second normal power 42 and the second maximum power 44 to the middle heater coil 164. Since the first normal power 32 equals to the second normal power 42 and the first maximum power 34 equals to the second maximum power 44, the center heater coil 162 and the middle heater coil 164 may be uniformly heated such that there is no difference in temperature therebetween in the plate 150.

In addition, the current control unit 216 may control the current and/or the electric power, based on the resistance of each of the heater coils 160. For example, the current control unit 216 may measure the resistance (R=V/I) of the heater coil 160 in real time, using the current sensing signal from the current sensor 200 and an input AC voltage (V). The current control unit 216 may measure a first resistance of the center heater coil 162 and a second resistance of the middle heater coil 164.

The comparison unit 222 may compare the first resistance with the first reference resistance 22 and compare the second resistance with the second reference resistance 24. The current control unit 216 may set the first resistance to have the same value as the first reference resistance 22 and may provide the first normal power 32 and the first maximum power 34 to the center heater coil 162. The current control unit 216 may set the second resistance to have the same value as the second reference resistance 24 and may provide the second normal power 42 and the second maximum power 44 to the middle heater coil 164. Since the first maximum power 34 equals to the second maximum power 44, the center heater coil 162 and the middle heater coil 164 may be uniformly heated such that there is no difference in temperature therebetween in the plate 150.

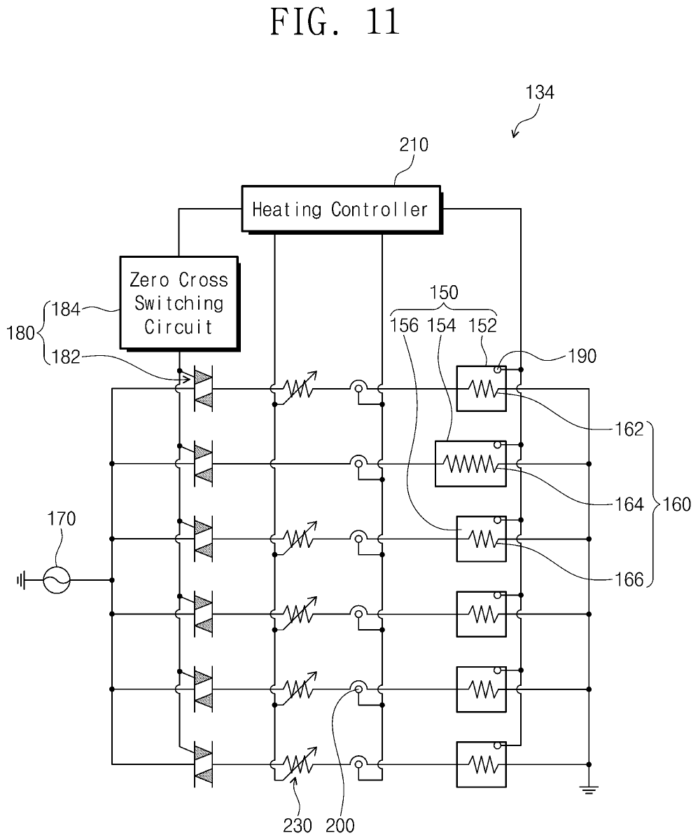

FIG. 11 illustrates the heating module 134 of FIG. 2 according to an exemplary embodiment of the present inventive concept.

Referring to FIG. 11, the heating module 134 may include a plurality of variable resistors 230 between the switching unit 180 and the heater coils 160. As an example, the variable resistors 230 may be provided between and connected to the switching devices 182 and the current sensor 200. For example, a variable resistor 230 may be connected to and between the center heater coil 162 and the switching device 182. As an additional example, another variable resistor 230 may be connected to and between the edge heater coils 166 and the switching devices 182. However, a variable resistor 230 might not be connected to the middle heater coil 164. The variable resistors 230 may change the resistances between the switching device 182 and the center heater coil 162 and between the edge heater coils 166 and the switching devices 182. If the plate 150 is temporarily cooled, the variable resistor 230 may decrease the current of the center heater coil 162. If the current of the center heater coil 162 is decreased by the variable resistor 230, the heating controller 210 may control the first maximum power 34 of the center heater coil 162 to have the same value as the second maximum power 44 of the middle heater coil 164. The center heater coil 162 and the middle heater coil 164 may be heated to the same temperature. Each of the variable resistors 230 may be used to decrease the current of a corresponding one of the edge heater coils 166. If the current of each of the edge heater coils 166 is decreased by each of the variable resistors 230, the heating controller 210 may control each of the edge heater coils 166. For example, the heating controller 210 may control each of the edge heater coils 166 by setting a maximum power applied thereto to the same value as the second maximum power 44 of the middle heater coil 164. The edge heater coils 166 and the middle heater coil 164 may be heated to the same temperature. This may make it possible to increase the heating temperature uniformity of the plate 150 and the heater coils 160. The power source 170, the switching unit 180, the temperature sensors 190, and the current sensors 200 may be configured to have substantially the same structure as those of FIG. 3.

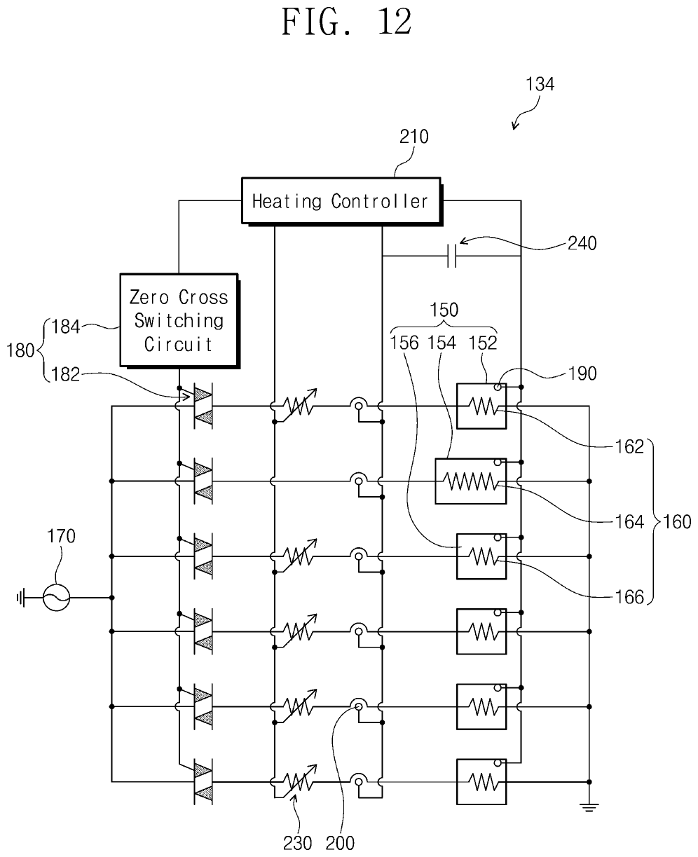

FIG. 12 illustrates the heating module 134 of FIG. 2 according to an exemplary embodiment of the present inventive concept.

Referring to FIG. 12, the heating module 134 may include a noise filter 240 between the temperature sensors 190 and the current sensors 200. For example, the noise filter 240 may be connected to the temperature sensors 190 and the current sensors 200. As an additional example, the noise filter 240 may be connected to the heating controller 210. The noise filter 240 may be configured to remove a noise (e.g., parasitic capacitance) between the temperature sensors 190 and the current sensors 200. For example, the noise filter 240 may include a capacitor. The plate 150, the heater coils 160, the power source 170, the switching unit 180, the temperature sensors 190, the current sensors 200 and the heating controller 210 may be configured to have substantially the same structure and function as those of FIG. 3, and the variable resistors 230 may be configured to have substantially the same structure and function as that of FIG. 11.

A method of fabricating a semiconductor device, using the fabrication system 100 according to an exemplary embodiment of the present inventive concept, will be described below.

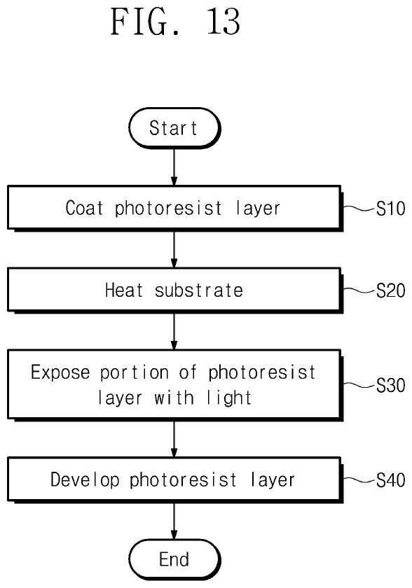

FIG. 13 illustrates a method of fabricating a semiconductor device, according to an exemplary embodiment of the present inventive concept.

The fabricating method of FIG. 13 may be a method of forming a photoresist pattern. As an example, the fabricating method may include coating a photoresist layer on a substrate (in S10), heating the substrate to cure the photoresist layer (in S20), exposing a portion of the photoresist layer with light (in S30), and developing the photoresist layer to form a photoresist pattern (in S40).

Referring to FIGS. 1 and 13, the spin coater 120 may form a photoresist layer on the substrate W using a coating process (in S10). The photoresist layer may be formed to have a substantially uniform thickness on a top surface of the substrate W by the spin coater 120.

Next, the substrate W may be heated by the baking device 130, and in this case, the photoresist layer on the substrate W may be cured by heat supplied from the baking device 130 (in S20).

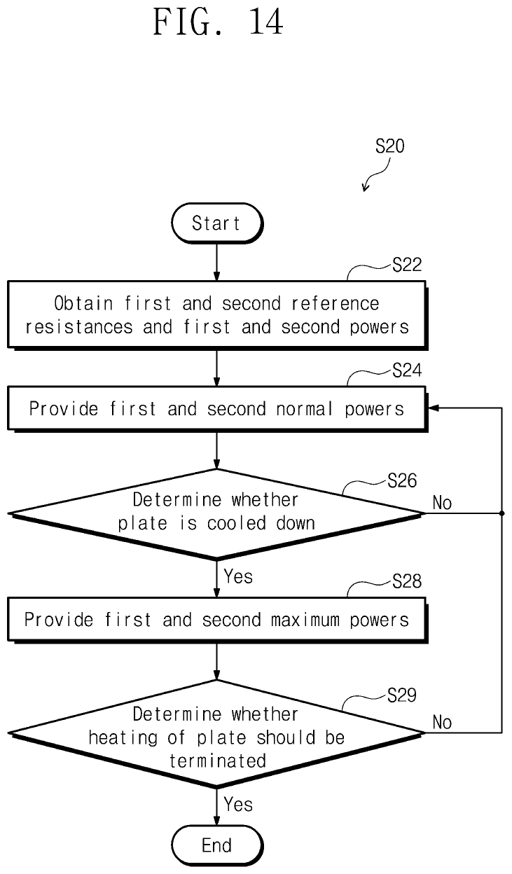

FIG. 14 illustrates the step S20 of heating the substrate W according to an exemplary embodiment of the present inventive concept.

Referring to FIG. 14, the heating process of the substrate W (in S20) may include obtaining information on the first and second reference resistances 22 and 24 and the first and second powers 30 and 40 (in S22). In addition, the heating process of the substrate W (in S20) may include providing the first and second normal powers 32 and 42 to the heater coils 160 (in S24), determining whether the plate 150 is cooled down (in S26), providing the first and second maximum powers 34 and 44 to the heater coils 160 (in S28), and determining whether the heating of the plate 150 should be terminated (in S29).

Referring to FIGS. 3, 5, and 14, the heating controller 210 may be configured to obtain information on the first and second reference resistances 22 and 24 and the first and second powers 30 and 40 (in S22). The information on the first and second reference resistances 22 and 24 and the first and second powers 30 and 40 may be provided from the memory unit 218.

For example, the heating controller 210 may provide the first normal power 32 to the center heater coil 162 and the edge heater coils 166 and provide the second normal power 42 to the middle heater coil 164 (in S24). For example, the plate 150 may be uniformly heated to a temperature of about 130° C.

If the substrate W is provided on the plate 150, the heating controller 210 may determine whether the plate 150 is cooled down (in S26). The heating controller 210 may measure a temperature of the plate 150, using the sensing signal of the temperature sensors 190.

If the plate 150 is determined to be in a cooled state, the heating controller 210 may provide the first and second maximum powers 34 and 44 to the heater coils 160 (in S28). The plate 150 may be reheated to a uniform temperature. The uniformity of the heating temperature of the plate 150 may be increased.

Next, the heating controller 210 may determine whether the heating of the plate 150 should be terminated (in S29). In the case where termination of the heating of the plate 150 should not occur, the heating controller 210 may conduct the steps S24, S26, S28 and S29 again until it is determined that termination of the heating of the plate 150 should occur.

Referring to FIGS. 1, 13 and 14, if the substrate W is heated and the photoresist layer is cured, the exposure device 300 may be used to irradiate at least a portion of the photoresist layer with light (in S30). The irradiated portion of the photoresist layer may be determined by positions of mask patterns in a reticle of the exposure device 300.

The photoresist layer may be developed by the developing device 140, and thus, photoresist patterns may be formed on the substrate W (in S40). The transfer module 138 (See FIG. 2) may transfer the substrate W to the index device 110, and the index device 110 may load the substrate W into the carrier 112.

According to an exemplary embodiment of the present inventive concept, a heating controller of a heating module may be configured to heat a plurality of heater coils with the same maximum powers, regardless of whether there is a difference in resistance between the heater coils, and this may make it possible to increase uniformity in heating temperature of a substrate.

As is traditional in the field of the inventive concepts, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, and the like, which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions. Also, each block, unit and/or module of the embodiments may be physically separated into two or more interacting and discrete blocks, units and/or modules without departing from the scope of the inventive concepts. Further, the blocks, units and/or modules of the embodiments may be physically combined into more complex blocks, units and/or modules without departing from the scope of the inventive concepts.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A heating module, comprising:
a plate including a plurality of heating regions;
a plurality of heater coils disposed in the plurality of heating regions;
a power source supplying an electric power to the plurality of heater coils;
a switching circuit connected to the plurality of heater coils and the power source to control the electric power;
temperature sensors disposed in the plurality of heating regions to sense temperatures of the plurality of heating regions;
current sensors connected to the switching circuit and the plurality of heater coils to sense currents supplied to the plurality of heater coils; and
a heating controller connected to the temperature sensors and the current sensors to measure temperatures of the heating regions,
wherein the heating controller is configured to detect the currents supplied to the plurality of heater coils and provides a maximum power to the heater coils regardless of a resistance difference of the plurality of heater coils, when a measured temperature is less than a predetermined temperature.

2. The heating module of claim 1, wherein the heating controller comprises:
a temperature control circuit connected to the temperature sensors; and
a current control circuit connected to the temperature control circuit and the current sensors.

3. The heating module of claim 2, wherein the heating controller further comprises a temperature processor, wherein the temperature processor is connected to the temperature control circuit and the heater coils and is configured to compare the measured temperature with the predetermined temperature.

4. The heating module of claim 2, wherein the heating controller further comprises:
a memory connected to the temperature control circuit and the current control circuit, wherein the memory is configured to store information on reference resistances of the plurality of heater coils;
a current calculation circuit configured to calculate reference currents using the reference resistances and the maximum power; and
a comparison circuit connected between the current calculation circuit and the current control circuit and is configured to compare the reference currents with the detected currents.

5. The heating module of claim 2, wherein the switching circuit comprises:
switches connected to the power source and the current sensors; and
a zero cross switching circuit connected to the switches and the current control circuit.

6. The heating module of claim 1, wherein the plurality of heating regions comprises:
a center region;
an edge region disposed around the center regions; and
a middle region disposed between the edge region and the center region.

7. The heating module of claim 6, wherein the plurality of heater coils comprises:
a center heater coil disposed in the center region;
an edge heater coil disposed in the edge region; and
a middle heater coil disposed in the middle region,
wherein the middle heater coil has a resistance higher than either a resistance of the center heater coil or a resistance of the edge heater coil.

8. The heating module of claim 7, further comprising variable resistors selectively connected to the center heater coil and the edge heater coil.

9. The heating module of claim 1, further comprising a noise filter connected to the current sensors and the temperature sensors.

10. The heating module of claim 9, wherein the noise filter comprises a capacitor.

11. A heating module, comprising:
a plate including first and second heating regions;
first and second heater coils disposed in the first and second heating regions, respectively;
a power source supplying an electric power to the first and second heater coils;
first and second switches connected to the power source and the first and second heater coils, respectively, to control the electric power;
current sensors connected to the first and second switches and the first and second heater coils, wherein the current sensors are configured to sense currents provided to the first and second heater coils; and
a heating controller configured to detect currents provided to the first and second heater coils by using sensing signals received from the current sensors,
wherein the heating controller provides a first maximum power to the first heater coil with a same value regardless of a resistance difference between the first and second heater coils, and
wherein the heating controller provides a second maximum power to the second heater coil with a same value as the first maximum power regardless of a resistance difference between the first and second heater coils.

12. The heating module of claim 11, wherein each of the current sensors comprises a current prober.

13. The heating module of claim 11, further comprising temperature sensors disposed in the first and second heating regions,
wherein each of the temperature sensors comprises a thermocouple.

14. The heating module of claim 11, wherein the first heating region is disposed inside the second heating region, and
the second heating region is shaped as an annulus.

15. The heating module of claim 11, further comprising a variable resistor selectively connected to the first heater coil,
wherein the resistance of the first heater coil is lower than the resistance of the second heater coil.

16. A system of fabricating a semiconductor device, comprising:
a spin coater coating a photoresist layer on a substrate; and
a baking device including a heating module configured to heat the substrate and to cure the photoresist layer,
wherein the heating module comprises:
a plate including first and second heating regions;
first and second heater coils disposed in the first and second heating regions, respectively;
a power source supplying an electric power to the first and second heater coils;
first and second switches connected to the power source and the first and second heater coils, respectively, to control the electric power;
current sensors connected to the first and second switches and the first and second heater coils and are configured to sense currents provided to the first and second heater coils; and
a heating controller configured to detect current provided to the first and second heater coils by using sensing signals received from the current sensors,
wherein the heating controller provides a first maximum power to the first heater coil with a same value regardless of a resistance difference between the first and second heater coils, and
wherein the heating controller provides a second maximum power to the second heater coil with a same value as the first maximum power regardless of a resistance difference between the first and second heater coils.

17. The system of claim 16, further comprising a temperature sensor disposed in each of the first and second heating regions.

18. The system of claim 16, wherein the baking device further comprises:
a base module disposed on the heating module;
a chamber module covering the plate of the heating module; and
a transfer module providing the substrate to the plate, when the chamber module opens.

19. The system of claim 16, further comprising a developing module configured to develop the photoresist layer and to form a photoresist pattern.

20. The system of claim 19, further comprising an index module configured to provide the substrate to the spin coater and to transfer the substrate from the developing module into a carrier.
